(19) United States
(12) Patent Application Publication
(10) Pub. No.: US 2005/0007162 A1
(43) Pub. Date: Jan. 13, 2005

(54) High speed, low power LVDS driver

(76) Inventor: Hector Torres, McKinney, TX (US)

Correspondence Address: Dan Swayze;Texas Instruments Incorporated, M/S 3999, P.O. Box 655474, Dallas, TX, 75265, US

(21) Appl. No.: 10/614,846

(22) Filed: Jul. 8, 2003

(51) Int. Cl. H03B 1/00

(52) U.S. Cl. 327/108

(57) ABSTRACT

A driver circuit (20) including a differential first pair of transistors (Q1, Q2), a voltage drive stage (26) including a second pair of transistors (Q3, Q4), a first pair of nodes (N1, N2) coupled to the first pair of transistors (Q1, Q2) and to the second pair of transistors (Q3, Q4), a second pair of nodes (N3, N4) coupled to the second pair of transistors (Q3, Q4), and a dynamic current switch (28) coupled to the second pair of nodes.

### FIELD OF THE INVENTION

The present invention relates to a low-voltage differential signaling (LVDS) driver and, more particularly, to a high speed, low power LVDS driver.

### BACKGROUND OF THE INVENTION

According to the International Engineering Consortium, low-voltage differential signaling (LVDS) uses high-speed analog circuit techniques to provide multi-gigabit data transfers and is a generic interface standard for high-speed data transmission. As a result of the Internet's tremendous growth, data transfers are increasing dramatically in all areas of communications. In addition, data streams for digital video, high-definition television, and color graphics are requiring higher and higher bandwidth. The digital communications deluge is the driving force for high-speed interconnects between chips, functional boards, and systems. LVDS's speed, low power, noise control, and cost advantages are popular in point-to-point applications for telecommunications, data communications, and displays.

In these applications, high-speed data moves within and between systems. Moving data within a system (intra-system data transfer) is the main use for LVDS solutions today. Moving information between systems (inter-system data transfer) requires standard communications protocols such as IEEE 1394, Fibre Channel, and Gigabit Ethernet. As the hardware and software overhead for inter-system protocols is too expensive to use for intra-system data transfers, a simple and low-cost LVDS link is an attractive alternative. Thus, LVDS solutions move information on a board; between boards, modules, shelves, and racks; or box to box. The transmission media can be copper cables or printed circuit board traces. Additionally, LVDS should soon carry protocols for intersystem communication.

FIG. 1 depicts a prior art high speed LVDS driver or circuit 10, which is a differential output driver. As a differential signal and common mode voltage enters the circuit 10, a certain amount differential voltage swings in one direction and the other producing a current steering effect on the differential transistor pair Q1 and Q2 thereby turning one of the pair on while turning the other one of the pair off. As such, either current IQ1 or current IQ2 will flow trough the resistors R1 and R2, respectively, producing an amount of differential drive voltage. With respect to nodes A and B, if node A is at a higher potential than node B, then transistor Q2 will shut off.

The voltage at node N1 follows the voltage at node N3, while the voltage at node N2 follows the voltage at node N4. The transistors Q3 and Q4 must be on in order to output their signals. In such a situation, power is constantly consumed by the transistors Q3 and Q4 and more current is present than is needed to create a differential voltage at the output thus resulting in an undesirable limitation of the circuit 10.

The following equations relate to the circuit 10:
the differential output voltage is: Vod=Vy−Vz;
RF1=RF2>>RL, when Vod>0; and
I_{Q4}=I_{Q5}+I_{RL} and I_{Q3}=I_{Q9}−I_{RL.}

For appropriate switching speed and output common mode regulation, I_{Q4}>0 and I_{Q3}>0. Assuming a fully symmetric architecture, I_{Q5}=I_{Q9}. Therefore I_{Q9}>I_{RL} and I_{Q5}>I_{RL}.

LVDS applications, for example, call for |Vod|=350 mV, and R_{L}=100 Ω which results in I_{RL}=3.5 mA. The power dissipation in the output stage is described as:
Pd=(I_{Q5}+I_{Q9})*Vcc

In typical applications Vcc=3.3 V, if I_{Q5}=I_{Q9}=5 mA the power dissipation in the output stage=330 mW It is typical for class A outputs to bum at least as much current as they want to drive.

It is therefore desirable for the present invention to overcome the problems and limitations described above that are involved in a LVDS driver.

### SUMMARY OF THE INVENTION

The present invention achieves technical advantages as a high speed, low power LVDS driver that reduces power dissipation in the output stage.

In one embodiment, a driver circuit comprises a differential first pair of transistors, a voltage drive stage comprising a second pair of transistors, a first pair of nodes coupled to the first pair of transistors and to the second pair of transistors, a second pair of nodes coupled to the second pair of transistors, and a dynamic current switch coupled to the second pair of nodes.

In another embodiment, a circuit comprises a voltage drive stage comprising a pair of transistors, a dynamic current switch coupled to the voltage drive stage, and a load resistor coupled to the pair of transistors, wherein current conducted through the pair of transistors are closely matched

In a further embodiment, a method of limiting current in a driver circuit having a pair of input nodes coupled to a differential first pair of transistors, a voltage drive stage comprising a second pair of transistors, a first pair of nodes coupled to the first pair of transistors and to the second pair of transistors, a second pair of nodes coupled to the second pair of transistors, and a dynamic current switch coupled to the second pair of nodes, comprises conducting a current through one of the second pair of transistors when one of the input nodes, one of the first pair of nodes, and one of the second pair of nodes is high, and conducting the current through the dynamic current switch.

In yet another embodiment, a method of limiting current in a circuit having a voltage drive stage comprising a pair of transistors and a dynamic current switch comprising a pair of tri-state switches coupled to a serially coupled transistor and resistor pair and to the pair of transistors, comprises contemporaneously conducting current through the pair of transistors, conducting current through at least one of the pair of tri-state switches, and conducting current through the dynamic current switch.

### BRIEF DESCRIPTION OF THE DRAWINGS

FIG. 1 illustrates a prior art driver circuit; and

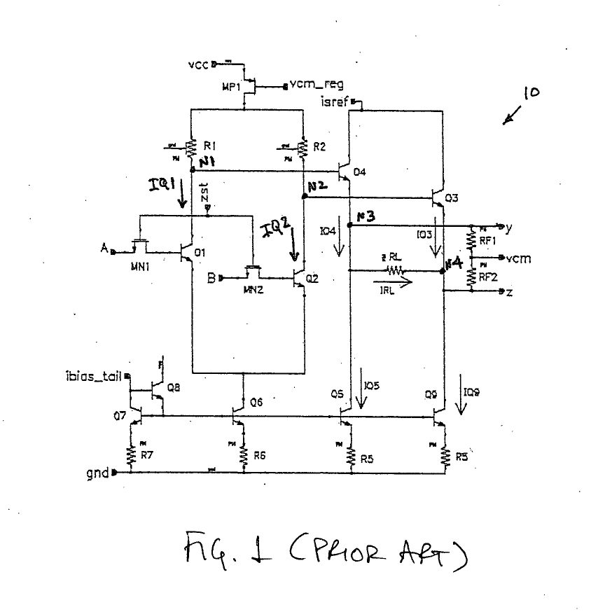

FIG. 2 illustrates a driver circuit in accordance with an exemplary embodiment of the present invention.

### DETAILED DESCRIPTION OF THE INVENTION

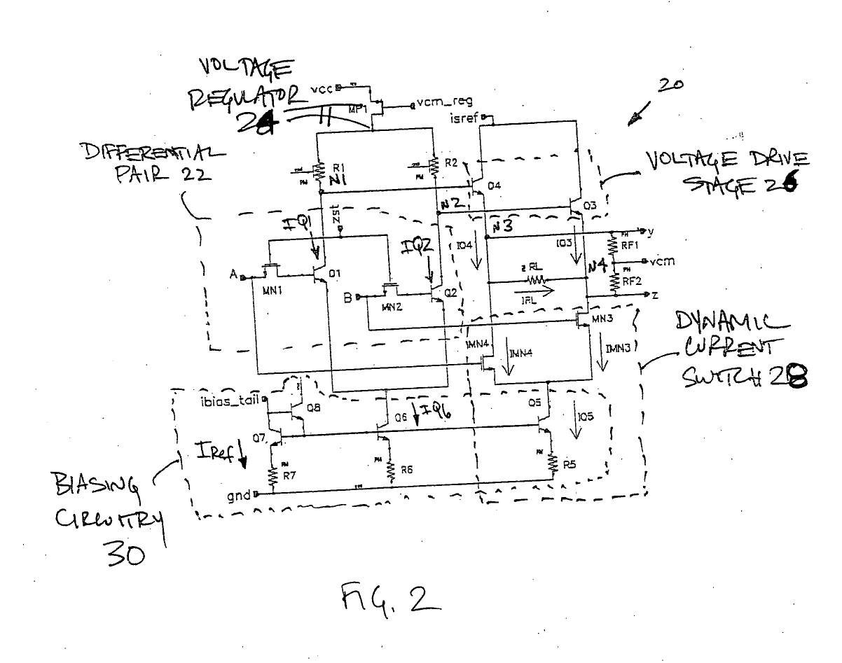

Referring now to FIG. 2, a driver circuit 20 of the present invention is presented. The driver circuit 20 comprises a differential pair 22 comprising a first pair of transistors Q1 and Q2, coupled to a pair of inputs A and B via a first pair of tri-state switches MN1 and MN2 (which may also be very small transistors), that are coupled to one another and to a logic pin ZST that is always high, thus forming a closed switch for the propagation of data from the input A to transistor Q1, and from the input B to the transistor Q2. The first pair of transistors Q1 and Q2 are respectively coupled to a first pair of parallel coupled resistors R1 and R2 via a first pair of nodes N1 and N2. The first pair of parallel coupled resistors R1 and R2 are coupled to a voltage regulator 24. MP1 is an active transistor part of a closed loop of the voltage regulator that maintains the Vcm node at 1.2V. The voltage Vcm is regulated via a closed loop comprised of an OTA (referenced to 1.2V) connected in between the Vcm and vcm_reg nodes, while the voltage Vcc is the supply voltage pin to the circuit 20.

The first pair of nodes N1 and N2 are respectively coupled to a second pair of transistors Q3 and Q4 which are further coupled to one another and to a node ISREF which can limit an amount of current that the transistors Q3 and Q4 can pass. The second pair of transistors Q3 and Q4, which form a voltage drive stage 26, are further respectively coupled to a load resistance RL via second pair of nodes N3 and N4. The second pair of nodes N3 and N4 are further respectively coupled to a resistor RF1 and an output node Y, and to a resistor RF2 and an output node Z. The resistors RF1 and RF2 are serially coupled to a common mode output node Vcm. The nodes N1 and N2 respectively follow the nodes N3 and N4.

The second pair of nodes N3 and N4 are also respectively coupled to a second pair of tri-state switches MN3 and MN4 which are further respectively coupled to the input nodes B and A. The second pair of tri-state switches MN3 and MN4 are coupled to a serially coupled transistor Q5 and a resistor R5. The switches MN3 and MN4, the transistor Q5, and the resistor R5 form a dynamic current switch 28.

The serially coupled transistor Q5 and the resistor R5, as well as the serially coupled transistor Q6 and the resistor R6, and the serially coupled transistor Q7 and the resistor R7 form the biasing circuitry 30. The transistor Q5 is coupled to the transistor Q6 which is coupled to the transistor Q7 and to the first pair of transistors Q1 and Q2. The resistors R5-R7 are coupled to a ground node. The ibias_tail node is part of the biasing structure of the circuit 20 and is supplied with an amount of current from a main biasing circuit. The transistor Q8 is a base current compensation circuit that improves the characteristics of the current mirror biasing the circuit (with transistors Q6 and Q7 being part of the biasing structure). Depending on a reference current Iref and the size of transistors Q5-Q7, a ratio of currents between the transistors Q5 and Q6, with respect to the reference current Iref, can be provided. For example, the current IQ6 can be 2×Iref, while the current IQ5 can be 5×Iref. This allows current to be directed across the circuit 20 and is based on the fact that bipolar transistors with the same Vbe drop will produce a ratio of currents equivalent to the ratio of their total emitter area. This particular biasing further employs emitter degeneration to improve layout matching as well as the current source characteristics of the mirrors.

One of the advantages of the circuit 20 is the inclusion of the dynamic current switch 28 at the output of the voltage drive stage 26. If, for example, the input node A is low, the input node B will be high, the nodes N1 and N3 will be high, while the nodes N2 and N4 will be low. For N1 to be high at a higher potential than N2, current flows thru R2 to create a potential difference between N1 and N2. The dynamic current switch 28 will steer the current from Q4 thru the load resistor RL by creating a differential voltage, thru the switch MN3 and thru the serially coupled transistor Q5 and the resistor R5. The differential voltage will be created on a pervious gain stage (not shown) coupled to the circuit 20.

If, for example, the input node A is high, the input node B will be low, the nodes N1 and N3 will be low, while the nodes N2 and N4 will be high. For N2 to be high at a higher potential than N1, current flows thru R1 to create a potential difference between N1 and N2. The dynamic current switch 28 will steer the current from Q3 thru the load resistor RL by creating a differential voltage on a previous gain stage, thru the switch MN4 and thru the serially coupled transistor Q5 and the resistor R5. The dynamic current switch 28 steers current depending on the polarity at the input nodes A and B.

The prior art the current IQ5 is at least greater than the current thru the resistance load RL. For example, if a load requirement of plus and minus 350 mV swing exists, and RL is 100 ohms, IQ5 has to be greater than 3.5 mA. In such a scenario, when current passes thru the transistor Q4, some current (bleeding current) will pass thru the transistor Q3 because voltage is constantly regulated on a previous gain stage. This bleeding current (in this case IQ3) passing thru the transistor Q3, for example, is IQ5 minus IRL, and is preferably smaller than the current IRL.

The output at nodes Y and Z is a differential voltage (Vod) that will constantly change magnitude between high and low polarities based on the input change at nodes A and B. This will allow the resistor RL to be driven in correspondence to a magnitude of the voltage drop across the resistor R1 or the resistor R2 (which are typically around 350 mV for LVDS levels). The resistors RF1 and RF2 monitor the common mode point of the output Vcm (which is equal to (VY+VZ) divided by 2). If, for example, the differential voltage is 350 mV, and Vcm is 1.2 v, output nodes Y and Z swing from 1.375 V to 1.15 V.

The following equations relate to the circuit 20 (symmetry is assumed and various previous definitions apply):
Vod=Vy−Vz; when Vod>0;
I_{Q4}I_{MN4}+I_{RL} and I_{Q3}=I_{MN3}−I_{RL}
If V_{Z}<V_{Y}, V_{A}<V_{B}, I_{MN4}=0, and I_{MN3}=I_{Q5.}

For appropriate switching speed and output common mode regulation, I_{Q4}>0, and I_{Q3}>0.

LVDS applications call for |Vod|=350 mV, and R_{L}=100 Ω. Therefore, I_{RL}=3.5 mA.

If, I_{Q5}=5 mA, the power dissipation in the output stage is:
Pd=I_{Q5}*Vcc

In typical applications, Vcc=3.3 V. If I_{Q5}=5 mA, power dissipation in the output stage is equal to 165 mW. This power dissipation in the output stage is 50% of the power dissipation in the prior art circuit 10. The difference is quite important, especially in the design of multi-channel devices, where the power saving (compared to the prior art circuit) will be:
P_{S}=N*I_{Q5}*Vcc; where N is the number of device channels.

Another one of the advantages of the circuit 20 is that the difference in the amount of currents IQ3 and IQ4 is not as large as the prior art currents IQ3 and IQ4. In the prior art circuit 10, currents IQ5 and IQ9 are constantly flowing. If node N3 is higher than node N4, then: IQ4=IQ5+IRL and IQ3=IQ9−RL. For example, if IQ5=IQ9=5 mA, and RL=3.5 mA, then IQ4=8.5 mA while IQ3=1.5 mA. Thus, unbalanced charging and discharging occurs between the transistors Q3 and Q4.

In the circuit 20, if, for example, the current IQ4 is conducted, IQ4=IRL, and IQ3=IQ5−RL. For example, if IQ5=5 mA, and IRL=3.5 mA, then IQ4=3.5 mA and IQ3=1.5 mA which provides a far more balanced charge and discharge between the transistors Q3 and Q4 of the present invention.

A further advantage of the circuit 20 is that because the currents conducted through the transistors Q3 and Q4 are better matched, the size of the transistors can be better matched (instead of requiring a small transistor to handle a 1.5 mA current and a large transistor to handle an 8.5 mA current, for example). Better matched transistors can lead to higher speeds through a circuit and to reduced complexity.

Another embodiment of the present invention involves a method of limiting current in a driver circuit having a pair of input nodes coupled to a differential first-pair of transistors, a voltage drive stage comprising a second pair of transistors, a first pair of nodes coupled to the first pair of transistors and to the second pair of transistors, a second pair of nodes coupled to the second pair of transistors, and a dynamic current switch coupled to the second pair of nodes, the method comprising conducting a current through one of the second pair of transistors when one of the input nodes, one of the first pair of nodes, and one of the second pair of nodes is high, and conducting the current through the dynamic current switch. The current conducted through the dynamic current switch is greater than a current conducted through a load resistor coupled to the second pair of nodes.

The method further comprises conducting current through another one of the second pair of nodes, and preferably contemporaneously conducting the current through the one of the second pair of nodes and the current through the other one of the second pair of nodes, wherein the current conducted through the other one of the second pair of nodes is equal to the current conducted through the dynamic current switch minus the current conducted through the load resistor, wherein the current conducted through the other one of the second pair of nodes is smaller than the current conducted through the load resistor, wherein the current conducted through the one of the second pair of nodes and the current conducted through the other one of the second pair of nodes are closely matched, and wherein the second pair of transistors are closely matched.

A further embodiment of the present invention involves a method of limiting current in a driver circuit having a voltage drive stage comprising a pair of transistors and a dynamic current switch comprising a pair of tri-state switches coupled to a serially coupled transistor and resistor pair and to the pair of transistors, the method comprising contemporaneously conducting current through the pair of transistors, conducting current through at least one of the pair of tri-state switches, and conducting current through the dynamic current switch, wherein the current conducted through the dynamic current switch is equal to the current conducted through the at least one of the pair of tri-state switches.

Although an exemplary embodiment of the present invention has been illustrated in the accompanied drawings and described in the foregoing detailed description, it will be understood that the invention is not limited to the embodiments disclosed, but is capable of numerous rearrangements, modifications, and substitutions without departing from the spirit of the invention as set forth and defined by the following claims.

1. A driver circuit, comprising:
a differential first pair of transistors to in put a differential signal;
a voltage drive stage comprising a second pair of transistors;
a first pair of nodes coupled to the first pair of transistors and to the second pair of transistors;
a second pair of nodes coupled to the second pair of transistors; and
a current switch coupled to the second pair of nodes to steer current based the polarity of said first pair of input nodes.

2. The driver circuit of claim 1 further comprising a first pair of resistors coupled to the first pair of nodes.

3. The driver circuit of claim 2 further comprising a voltage regulator coupled to the first pair of resistors.

4. The driver circuit of claim 1 further comprising a load resistor coupled to the second pair of nodes.

5. The driver circuit of claim 1 further comprising a second pair of resistors coupled to the second pair of nodes.

6. The driver circuit of claim 5 further comprising a pair of output nodes coupled to the second pair of resistors.

7. The driver circuit of claim 5 further comprising an output voltage coupled to the second pair of resistors.

8. The driver circuit of claim 1 further comprising three serially coupled transistor and resistor pairs, wherein the first serially coupled transistor is coupled to an input node, wherein the second serially coupled transistor is coupled to the differential first pair of transistors, and wherein the third serially coupled transistor comprises a portion of the dynamic current switch.

9. The driver circuit of claim 8, wherein the first transistor is coupled to the second transistor.

10. The driver circuit of claim 8, wherein the second transistor is coupled to the third transistor.

11. The driver circuit of claim 8, further comprising a ground, wherein the three resistors of the serially coupled transistor and resistor pairs are coupled to the ground.

12. The driver circuit of claim 8, further comprising a an additional transistor coupled to the input node.

13. The driver circuit of claim 1, wherein a first one of the first pair of nodes follows a first one of the second pair of nodes.

14. The driver circuit of claim 1, wherein a second one of the first pair of nodes follows a second one of the second pair of nodes.

15. The driver circuit of claim 1, further comprising a pair of input nodes coupled to the differential first pair of transistors and to the dynamic current switch.
